(19) United States
(12) Patent Application Publication
(10) Pub. No.: US 2017/0110416 A1
(43) Pub. Date: Apr. 20, 2017

(54) CHIP PACKAGE HAVING A PROTECTION PIECE COMPLIANTLY ATTACHED ON A CHIP SENSING SURFACE

(71) Applicants: POWERTECH TECHNOLOGY INC., Hsinchu (TW); Powertech Technology (Suzhou) Ltd., Suzhou (CN)

(72) Inventors: Hong-Yan MIAO, Hsinchu (TW); Yi HUA, Hsinchu (TW); Zhi-Ling LIU, Hsinchu (TW); Ruo-Xu JIN, Hsinchu (TW)

(21) Appl. No.: 15/160,711

(22) Filed: May 20, 2016

(30) Foreign Application Priority Data
Oct. 15, 2015 (CN) 201510666987.5

(51) Int. Cl. H01L 23/00; H01L 23/31; G06K 9/00; H01L 23/498

(52) U.S. Cl. CPC H01L 23/564; H01L 23/49811; H01L 23/49838; H01L 23/3114; G06K 9/00053

(57) ABSTRACT

Disclose is a chip package having an adhesive protection piece compliantly attached on the chip sensing surface, comprising a substrate, a main chip disposed on the substrate, an adhesive protection piece covering the main chip and an encapsulant encapsulating the main chip. The main chip has a chip sensing surface facing to a direction away from the substrate and a connection terminal electrically connected to the substrate. The adhesive protection piece essentially consists of a pick-and-place sheet and a die-bonding layer. The encapsulant completely encapsulates the die-bonding layer without covering the external surface of the pick-and-place sheet. The adhesive protection piece is compliantly attached to the chip sensing surface by pick-and-place processes so that the die-bonding layer is attached to the chip sensing surface with a constant adhesive gap. Moreover, the external surface of the pick-and-place sheet is parallel to the chip sensing surface which is not affected by the horizontal deviation of the substrate to resolve the sensing distortion issue when a sensing chip is covered by an adhesive protection piece.

### FIELD OF THE INVENTION

The present invention relates to semiconductor packages of sensing chips, and more specifically to a chip package having a protection piece disposed on a chip sensing surface to be implemented on a fingerprint recognition chips with lid-covered packaging.

### BACKGROUND OF THE INVENTION

Semiconductor chips are cores of microelectronic devices. They can be classified according to different functions such as IC chips, LED chips, sensor chips, solar cell chips, and MEMS chips. Therein, sensor chips are further categorized into fingerprint recognition chips, image sensor chips, pressure sensor chips, etc. Chips with different functions need corresponding package structures to conform to the requirements of protecting chips, transmitting electrical signals of chips outside without affecting the functions of chips.

In conventional semiconductor package for fingerprint recognition chip, the sensing surface is exposed from the package structure so that human finger can touch the sensing surface. However, the exposed sensing surface is vulnerable for contamination or destruction leading to products failure.

As disclosed in U.S. Pat. No. 8,803,258 B2 entitled “finger sensor including capacitive lens and associated methods”, Gozzini et al taught that a fingerprint recognition device comprises a mounting substrate, an integrated circuit chip carried by the mounting substrate having an array of electric field-based fingerprint recognition elements, and an electrical connector coupling the mounting substrate with the IC chip. In additional, the fingerprint recognition device further comprises a protective plate attached over the array of electric field-based fingerprint recognition elements. The protective plate is defined as a capacitive lens implemented for the array of electric field-based finger sensing elements. Moreover, the fingerprint recognition device further comprises an encapsulating material adjacent the mounting substrate and the IC chip and around the electrical connector. The width of the protective plate located on the shorter side of the chip must be larger for solder connecting at least one electrical conductor is carried by the protective plate to the mounting substrate. The length of the protective plate located on the longer side of the chip must be shorter to avoid touching the wire bonds bonded on the bonding pads of the chip, therefore, the protective plate cannot be compliantly attached to the sensing surface.

Normally, conventional process of attaching a protective plate is done by attaching a mother plate including a plurality of protective plates on a plurality of chips on the substrate. The mounting horizon of the mother plate is followed by the horizon of the substrate. After the adhesive disposed between the chips and the substrate is cured, the error of the mounting horizon of the mother plate corresponding to the chips may affect the gap between the sensor chips and the protective plate leading to poor sensitivity of the sensor chips so that it easily occurs sensing distortion issues after disposing the mother plate having the protective pieces on the sensor chips.

### SUMMARY OF THE INVENTION

In order to resolve the above-mentioned issues, the main purpose of the present invention is to provide a chip package having protection piece compliantly attached on a chip sensing surface to avoid production of inaccurate sensors. In this way, the manufacturing yield and production efficiency is increased.

The second purpose of the present invention is to provide a chip package having protection piece compliantly attached on the chip sensing surface to conform to the requirements of Chip Scale Package (CSP) without having an opening at the bottom of the chip. Furthermore, the packaging process is simplified to avoid additional packaging cost and keep the structural integrity of the fingerprint recognition chip.

According to the present invention, a chip package having protection piece compliantly attached on chip sensing surface is disclosed. The chip package comprises a substrate, a main chip, an adhesive protection piece, and an encapsulant. The main chip is disposed on the substrate. The main chip has a chip sensing surface and a connecting terminal. The chip sensing surface faces to a direction away from the substrate. The connecting terminal is electrically connected to the substrate. The adhesive protection piece comprises a pick-and-place sheet and a first die-bonding layer. The pick-and-place sheet has an internal surface and an external surface. The first die-bonding layer covers the internal surface of the pick-and-place sheet. The adhesive protection piece is compliantly attached to the chip sensing surface using pick-and-place process. In this way, the first die-bonding layer is adhered to the chip sensing surface. Therein, a distance between the internal surface of the pick-and-place sheet and the chip sensing surface is equivalent to the thickness of the first die-bonding layer. The external surface of the pick-and-place sheet is parallel to the chip sensing surface and is not affected by the level difference to the substrate. The encapsulant is formed on the substrate to encapsulate the main chip. The encapsulant has a height corresponding to the substrate. The height of the encapsulant is greater than the thickness of the main chip. The encapsulant does not exceed the external surface of the pick-and-place sheet. In this way, the height of the encapsulant is less than a height of the external surface of the pick-and-place sheet corresponding to the substrate. Furthermore, the encapsulant encapsulates at least one side of the first die-bonding layer. And the external surface of the pick-and-place sheet is exposed from the encapsulant. Therefore, the external surface of the pick-and-place sheet and the chip sensing surface of the main chip are well aligned in parallel which helps eliminate sensing distortion issues after disposing the protective piece on the sensor chip.

### BRIEF DESCRIPTION OF THE DRAWINGS

FIG. 1 is a cross-sectional view of a chip package having protection piece compliantly added on chip sensing surface according to a first embodiment of the present invention.

FIG. 2 is a cross-sectional view of a chip package having protection piece compliantly attached on chip sensing surface according to a second embodiment of the present invention.

FIGS. 3A to 3I are cross-sectional views of the chip package of the second embodiment, each corresponding to a step of the manufacturing process of the chip package.

FIG. 4 is a cross-sectional view of a chip package having protection piece compliantly attached on chip sensing surface according to a third embodiment of the present invention.

FIG. 5 is a cross-sectional view of a chip package having protection piece compliantly attached on chip sensing surface according to a fourth embodiment of the present invention.

FIG. 6 is a cross-sectional view of a chip package having protection piece compliantly attached on chip sensing surface according to a fifth embodiment of the present invention.

FIGS. 7A to 7G are cross-sectional views of the chip package of the fifth embodiment, each corresponding to a step of the manufacturing process of the chip package.

FIG. 8 is a cross-sectional view of a chip package having protection piece compliantly attached on chip sensing surface according to a sixth embodiment of the present invention.

FIG. 9 is a cross-sectional view of a chip package having protection piece compliantly attached on chip sensing surface according to a seventh embodiment of the present invention.

FIGS. 10A to 10F are cross-sectional views of the chip package of the seventh embodiment, each corresponding to a step of the manufacturing process of the chip package.

FIG. 11 is a cross-sectional view of a chip package having protection piece compliantly attached on chip sensing surface according to the eighth embodiment of the present invention.

### DETAILED DESCRIPTION OF THE INVENTION

With reference to the attached drawings, the present invention is described by means of the embodiment(s) below where the attached drawings are simplified for illustration purposes only to illustrate the structures or methods of the present invention by describing the relationships between the components and assembly in the present invention. Therefore, the components shown in the figures are not expressed with the actual numbers, actual shapes, actual dimensions, nor with the actual ratio. Some of the dimensions or dimension ratios have been enlarged or simplified to provide a better illustration. The actual numbers, actual shapes, or actual dimension ratios may be selectively designed and disposed and the detail component layouts may be more complicated.

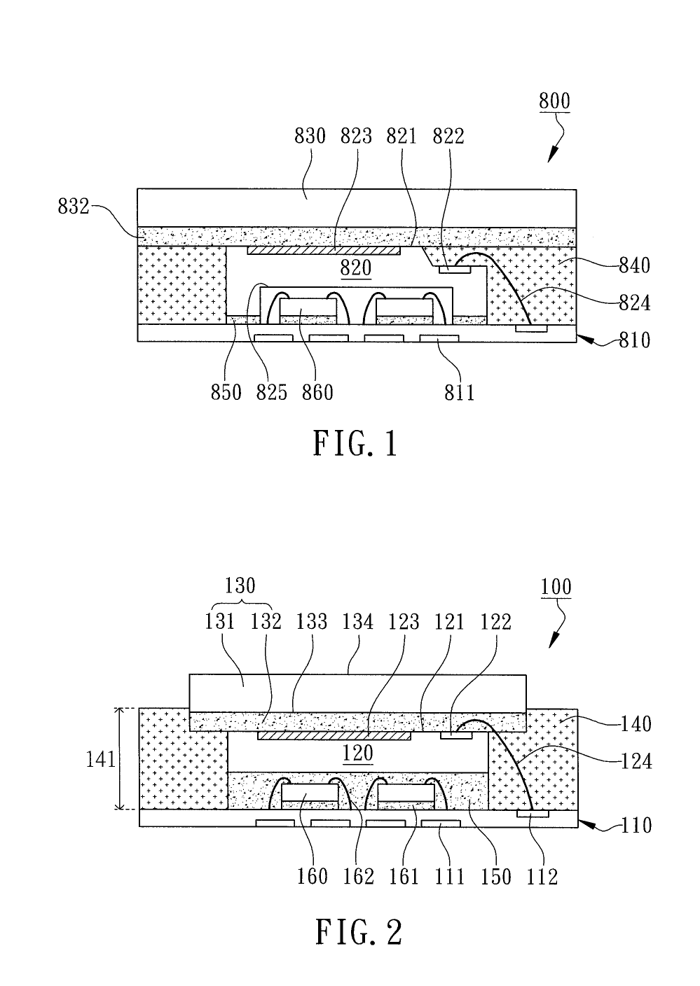

According to the first embodiment of the present invention, a cross-sectional view of a chip package 800 having a protection piece 830 compliantly attached on a chip sensing surface 821 is shown in FIG. 1. The chip package 800 comprises a substrate 810, a main chip 820, a protective piece 830, and an encapsulant 840. The substrate 810 is a circuitry carrier having a plurality of external connecting pads 811. The external connecting pads 811 are used to electrically connect the chip package 800 to a printed circuit board. A plurality of substrate 810 may form a mother plate used during the packaging process.

A plurality of main chips 820 are disposed on the mother plate of the substrate 810. Each of the plurality of main chips 820 may be a fingerprint recognition chip. The main chip 820 may have a chip sensing surface 821 and a connecting terminal 822. The chip sensing surface 821 may include a finger sensing area 823. The chip sensing surface 821 faces to a direction away from the substrate 810. The connecting terminal 822 is electrically connected to the substrate 810. The chip sensing surface 821 is a part of the main chip 820 used to detect external information. The connecting terminal 822 may be a terminal used to electrically connect to another circuit. The main chip 820 may have a trench wherein the connecting terminal 822 is disposed. The connecting terminal 822 may be electrically connected to the substrate 810 by using a wire bond 824 through wire-bonding process.

A plurality of protective plates 830 used to form a mother plate are disposed on a plurality of main chips 820. The protective piece 830 may be made of a transparent material such as a glass or a transparent plastic. A first die-bonding layer 832 is used to adhere the protection piece 830 to the chip sensing surface 821 of the main chip 820. The protection piece 830 is used to cover the fingerprint recognition area 823. Through a molding process, the encapsulant 840 may be formed on the substrate 810 to encapsulate the peripheries of the main chip 820 and the wire bond 824. Utilizing the process of singulation cutting, the mother substrate formed using the plurality of substrates 810 and the mother plate formed using the plurality of protection pieces 830 are cut off substantially at the same time to make the chip package 800 as shown in FIG. 1. The encapsulant 840 may not completely encapsulate the first die-bonding layer 832.

The protection piece 830 may be disposed on the substrate 810 to be in parallel with the main chip 820. When the main chip 820 and the substrate 810 are non-parallel to each other, the protection piece 830 and the chip sensing surface 821 may also be non-parallel to each other. In this way, the gap between the first die-bonding layer 832 and the chip sensing surface 821 may not keep constant, thus, leading to sensing distortion after adding the protection piece 830.

In order to eliminate the deviation of parallelism between the protection piece 830 and the chip sensing surface 821, a second die-bonding layer 850, such as Die Attach Material (DAM), with thin and uniform thickness may be arranged in the chip package 800. The second die-bonding layer 850 is pre-formed on the main chip 820 to adhere the main chip 820 to the substrate 810.

In addition, when a second chip 860, such as an Application Specific Integrated Circuit (ASIC) chip, is needed to be disposed between the main chip 820 and the substrate 810 of the chip package 800, a backside cavity 825 may be formed on the main chip 820 during wafer-level process to accommodate the second chip 860. The forming of the backside cavity 825 and the patterned second die-bonding layer 850 for the main chip 820 is highly difficult, thus, making the packaging process much more complicated. This may cause a higher manufacture cost and lower yield.

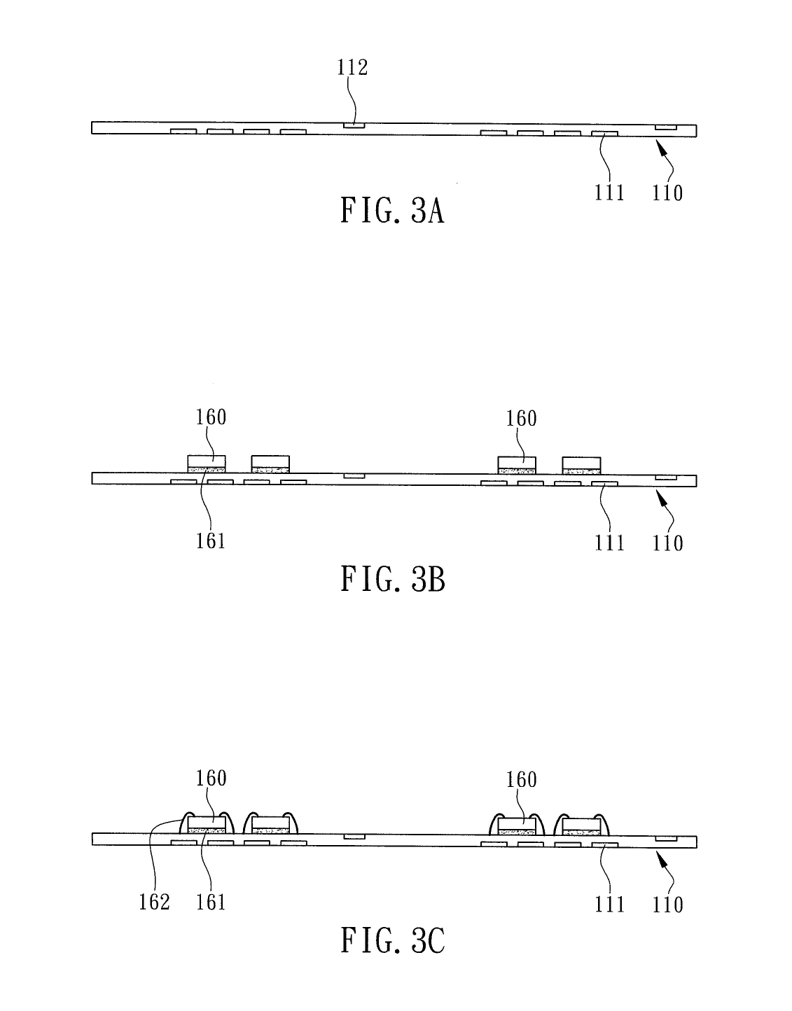

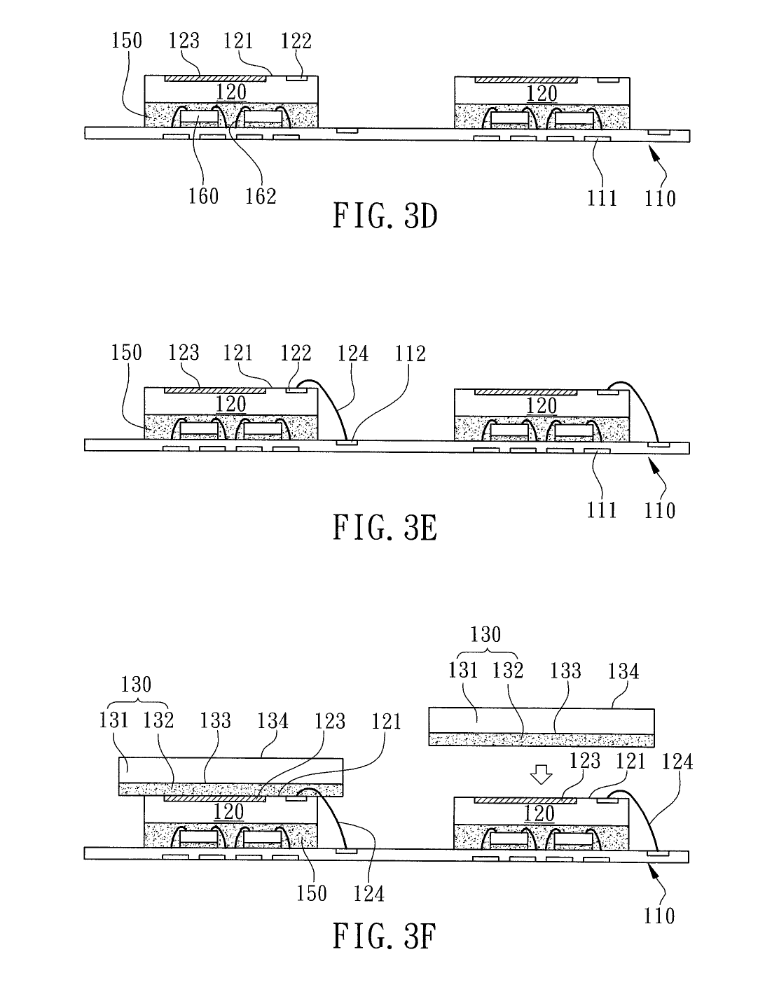

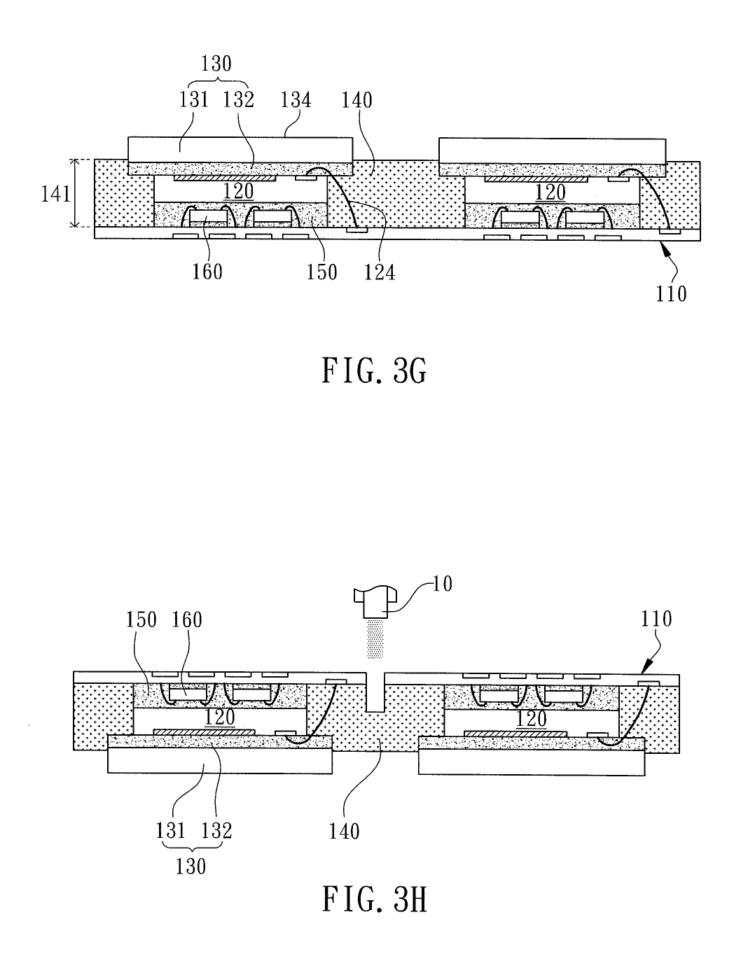

According to the second embodiment of the present invention, a cross-sectional view of a chip package 100 having an adhesive protection piece compliantly attached on the chip sensing surface is illustrated in FIG. 2. And FIG. 3A to FIG. 3I illustrate cross-sectional views of the chip package 100, each corresponding to a step of the manufacturing process of the chip package. The chip package 100 comprises a substrate 110, a main chip 120, an adhesive protective piece 130, and an encapsulant 140.

The substrate 110 has a plurality of external connecting pads 111 disposed on the bottom surface and a plurality of internal bonding fingers 112 disposed on the top surface. The external connecting pads 111 are used for external electrical connection and the internal bonding fingers 112 are used for the internal electrical connection such as electrically connecting to the main chip 120. The substrate 110 may be a circuit carrier such as a printed circuit board, a flexible circuit board, or a ceramic substrate.

The main chip 120 is disposed on the substrate 110. The main chip 120 is a semiconductor chip, such as a fingerprint sensor chip. The invention is not limited to the fingerprint sensor chip, the main chip 120 may be an image sensor chip or other type of chips. The so-called “main chip” may be the larger chip or the only sensor chip in the chip package 100. The main chip 120 has a chip sensing surface 121 and a connecting terminal 122. The chip sensing surface 121 may be used to sense and receive external information and the connecting terminal 122 is an electrical terminal disposed on the chip sensing surface 121. The chip sensing surface 121 faces to a direction away from the substrate 110. And, the connecting terminal 122 is electrically connected to internal bonding fingers 112 of the substrate 110.

The adhesive protective piece 130 comprises a pick-and-place sheet 131 and a first die-bonding layer 132. The pick-and-place sheet 131 and the first die-bonding layer 132 may be major components of the adhesive protective piece 130. The pick-and-place sheet 131 may be made of an uniformly hard material that does not affect the sensing capability of the main chip 120, i.e. glass, sapphire, or microcrystalline Zirconium. The first die-bonding layer 132 may be made of an uniformly cured adhesive material that does not affect the sensing capability of the main chip 120, i.e. epoxy without spacer or Die Attach Material (DAM). The pick-and-place sheet 131 has an internal surface 133 and an external surface 134. The first die-bonding layer 132 is disposed on the internal surface 133 of the pick-and-place sheet 131. The first die-bonding layer 132 has an appropriate thickness to encapsulate the embedded connecting wires. The adhesive protective piece 130 may fully cover the top of the main chip 120. The area of the external surface 134 of the adhesive protective piece 130 is greater than the area of the chip sensing surface 121 of the main chip 120 but less than the area of the top surface of the substrate 110. The adhesive protective piece 130 is compliantly attached to the chip sensing surface 121 by the pick-and-place process to adhere the first die-bonding layer 132 to the chip sensing surface 121 with a constant adhesive gap. After disposing the adhesive protective piece 130 on the main chip 120, the first die-bonding layer 132 may have a predetermined thickness before going through the curing process. The pick-and-place process may be done by automatic machines. Moreover, the external surface 134 of the pick-and-place sheet 131 is parallel to the chip sensing surface 121 and is independent from a leveling of the substrate 110. The term “compliantly attached” may mean that all the area of the chip sensing surface 121 are covered by the adhesive protective piece 130 and adhered by the first die-bonding layer 132, wherein the chip sensing surface 121 and the external surface 134 of the pick-and-place piece 131 are parallel to each other so that the first die-bonding layer 132 has a uniform thickness after curing. In the present embodiment, when the connecting terminals 122 are disposed on the chip sensing surface 121, the first die-bonding layer 132 may further cover the connecting terminals 122.

The encapsulant 140 is disposed on the substrate 110 to encapsulate the peripheries of the main chip 120 for electric isolation. An example of the encapsulant 140 may be an epoxy molding compound (EMC). The encapsulant 140 may have an encapsulated height 141 corresponding to the substrate 110 that is greater than the thickness of the main chip 120 but less than or equal to a cover height of the external surface 134 of the pick-and-place sheet 131 corresponding to the substrate 110. In this way, the encapsulant 140 may completely encapsulate the first die-bonding layer 132 without covering the external surface 134 of the pick-and-place sheet 131. Therefore, the external surface 134 of the pick-and-place sheet 131 is compliantly attached to the chip sensing surface 121 to avoid sensing distortion when the adhesive protective piece 130 is added to the sensor chip 120.

The chip package 100 may further comprise a second die-bonding layer 150 disposed between the main chip 120 and the substrate 110. A covered area of the second die-bonding layer 150 is less than a covered area of the first die-bonding layer 132. The second die-bonding layer 150 is an adhesive used to adhere the main chip 120 to the substrate 110. The second die-bonding layer 150 may be an epoxy resin or Film-On-Die (FOD) adhesive used for covering at least a smaller chip under the main chip 120. The thickness of the FOD layer may be thicker than the thickness of a Film-On-Wire (FOW) adhesive. Furthermore, the accuracy for the thickness control for covering capability of FOW is less accurate than that of the FOD. The leveling of the main chip 120 to the substrate 110 need not be considered. Thus, the disposing of the main chip 120 having a chip sensing surface 121 to the substrate 110 is performed using normal die-bonding process.

In the embodiment, the chip package 100 may further comprise at least a minor chip 160 disposed on the substrate 110 and located between the main chip 120 and the substrate 110. The thickness of the second die-bonding layer 150 may be greater than the thickness of the first die-bonding layer 132 so that the second die-bonding layer 150 may fully cover the minor chip 160. The minor chip 160 may be an ASIC chip or a controller chip. The minor chip 160 is disposed to the substrate 110 by a third die-bonding layer 161. And the minor chip 160 may be electrically connected to the substrate 110 through at least a bonding wire 162. The bonding wire 162 may be a gold wire. The second die-bonding layer 150 may further encapsulate the third die-bonding layer 161 and the bonding wire 162. Therefore, the main chip 120 may not be compliantly attached to the substrate 110. The level difference between the main chip 120 and the substrate 110 may not affect the parallelism between the external surface 134 of the pick-and-place sheet 131 and the chip sensing surface 121 of the main chip 120. Thus, sensing distortion may be avoided after bonding the adhesive protective piece 130 onto top of the main chip 120 and hiding the minor chip 160 under the main chip 120.

In the embodiment, the connecting terminal 122 is a bonding pad located at a periphery of the chip sensing surface 121 and is connected to the internal bonding fingers 112 of the substrate 110 through a bonding wire 124 which may be a gold wire. In the present embodiment, the wire loop section of the bonding wire 124 above the main chip 120 is preferably embedded inside the first die-bonding layer 132 so that the first die-bonding layer 132 is compliantly attached to the chip sensing surface 121 and the location of the connecting terminal 122 do not need any special process to form trench on the main chip 120.

The chip sensing surface 121 may include a fingerprint sensing area 123. The fingerprint sensing area 123 includes a recognition element array used to receive external information (not shown in the figures). The first die-bonding layer 132 may cover the whole fingerprint sensing area 123. Therefore, the first die-bonding layer 132 is compliantly attached to the fingerprint sensing area 123 to enhance sensing sensitivity.

The packaging processes of the chip package 100 are further described through FIG. 3A to FIG. 3I. As shown in FIG. 3A, a substrate 110 is provided. The substrate 110 is fixed on a working station. The substrate 110 has a plurality of external connecting pads 111 and a plurality of internal bonding fingers 112 at opposing surfaces. Then, as shown in FIG. 3B, at least a minor chip 160 is disposed on the substrate 110. The minor chip 160 is disposed on the substrate 110 using the third die-bonding layer 161. Then, as shown in FIG. 3C, the bonding wires 162 are formed on the substrate 110 using wire-bonding process. The minor chip 160 is electrically connected to the substrate 110 through the bonding wires 162. Then, as shown in FIG. 3D, the main chip 120 is disposed on the substrate 110. The second die-bonding layer 150 is used to encapsulate the minor chip 160 and the bonding wires 162 and is used to adhere the main chip 120 on the substrate 110. The chip sensing surface 121 of the main chip 120 includes the fingerprint sensing area 123 and a peripheral area for disposing the connecting terminals 122. The chip sensing surface 121 faces to a direction away from the substrate 110. Then, the second die-bonding layer 150 is cured. Then, as shown in FIG. 3E, the bonding wires 124 are disposed to electrically connect the connecting terminals 122 of the main chip 120 to the internal bonding fingers 112 of the substrate 110. Then, as shown in FIG. 3F, the pick-and-place process of the adhesive protective piece 130 is executed. The adhesive protective piece 130 is compliantly attached to the chip sensing surface 121 of the main chip 120. The adhesive protective piece 130 comprises a pick-and-place sheet 131 and a first die-bonding layer 132. The first die-bonding layer 132 is adhered to the chip sensing surface 121 with a constant adhesive gap. The wire loop sections of the bonding wires 124 above the main chip 120 may be preferably embedded inside the first die-bonding layer 132. Then, as shown in FIG. 3G, the molding process is executed to dispose an encapsulant 140 on the substrate 110 to encapsulate the main chip 120 and the first die-bonding layer 132. The encapsulant 140 has an encapsulated height 141 corresponding to the substrate 110 which is greater than the thickness of the main chip 120 but less than or equal to the external surface 134 of the pick-and-place sheet 131 corresponding to the substrate 110. In this way, the encapsulant 140 fully encapsulates the first die-bonding layer 132 without encapsulating the external surface 134 of the pick-and-place sheet 131. Then, as shown in FIG. 3H, a singulation process is executed where the bottom surface of the substrate 110 of the chip packages 100 is faced to a laser cutting device 10. The laser cutting device 10 may cut through the substrate 110 and parts of the encapsulant 140 and then further cut through the encapsulant 140 without cutting the pick-and-place sheet 131 and the first die-bonding layer 132. In this way, the cutting stress is reduced to avoid any possible peeling of the hard protective plate covering the main chip 120. A plurality of individual chip packages 100 generated after the singulation process are shown in FIG. 3I. Since the pick-and-place sheet 131 of the adhesive protective piece 130 is not cut during the singulation process, the adhesive gap of first die-bonding layer 132 is kept constant without any crack.

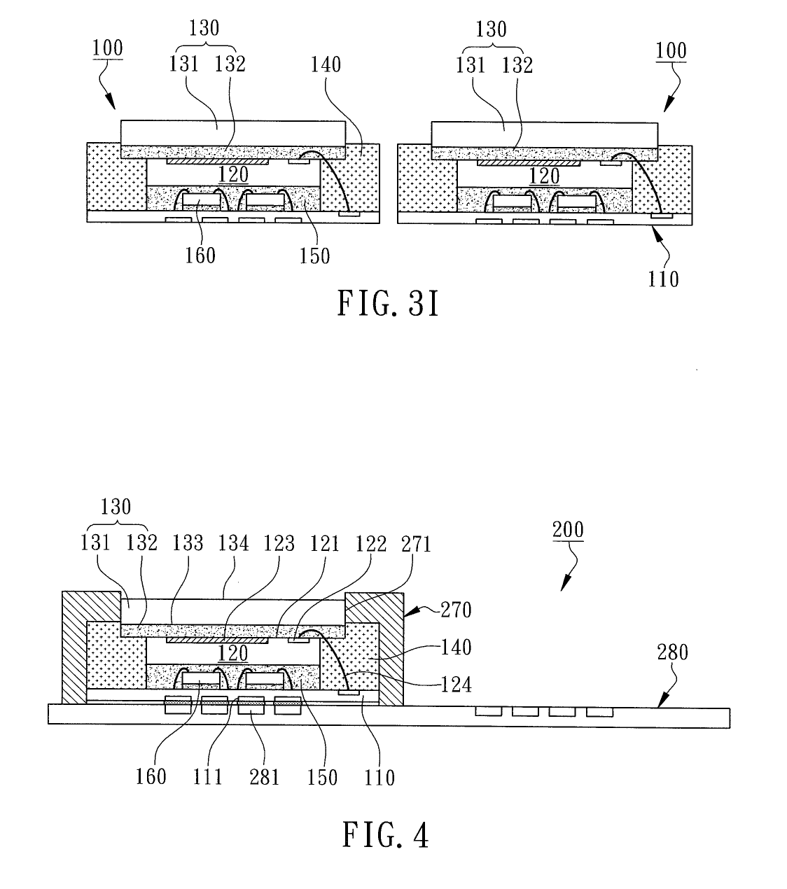

According to the third embodiment of the present invention, a cross-sectional view of a chip package 200 having an adhesive protection piece compliantly attached on the chip sensing surface is illustrated in FIG. 4. Except the additional major components such as a metal cap 270 and a printed circuit board 280, the chip package 200 is relatively the same as the chip package 100 as described in the second embodiment where the corresponding components have the same names and numbers as mentioned in the second embodiment are followed without any further detail description. The chip package 200 comprises a substrate 110, a main chip 120, an adhesive protective piece 130 and an encapsulant 140.

The main chip 120 is disposed on the substrate 110 where the main chip 120 is a fingerprint sensor chip. The substrate 110 has a plurality of external connecting pads 111 and an internal bonding finger 112. The main chip 120 has a chip sensing surface 121 and a connecting terminal 122 on the chip sensing surface 121 where the chip sensing surface 121 faces to a direction away from the substrate 110. The connecting terminal 122 is electrically connected to the substrate 110 through the bonding wire 124. The adhesive protective piece 130 comprises a pick-and-place sheet 131 and a first die-bonding layer 132 where the pick-and-place sheet 131 has an internal surface 133 and an external surface 134. The first die-bonding layer 132 may be disposed on the internal surface 133 of the pick-and-place sheet 131 in advance. The adhesive protective piece 130 is compliantly attached on the die sensing surface 121 using a pick-and-place process. In this way, the first die-bonding layer 132 is attached to the chip sensing surface 121 with a constant adhesive gap. The external surface 134 of the pick-and-place sheet 131 may be parallel to the chip sensing surface 121 and may not be affected by the leveling of the substrate 110. The wire loop section of the bonding wire 124 above the main chip 120 is preferably embedded inside the first die-bonding layer 132. Moreover, the encapsulant 140 is formed over the substrate 110 to encapsulate the main chip 120 and the first die-bonding layer 132. The encapsulant 140 has an encapsulated height 141 greater than the thickness of the main chip 120 but not exceeding the external surface 134 of the pick-and-place sheet 131. In this way, the encapsulant 140 encapsulates at least one side of the first die-bonding layer 132 without encapsulating the external surface 134 of the pick-and-place sheet 131. The chip package 200 may further comprise a second die-bonding layer 150 disposed between the main chip 120 and the substrate 110. A covered area of the second die-bonding layer 150 is less than a covered area of the first die-bonding layer 132. At least a minor chip 160 may be disposed on the substrate 110 located between the main chip 120 and the substrate 110. Therein, the thickness of the second die-bonding layer 150 is greater than the thickness of the first die-bonding layer 132. In this way, the second die-bonding layer 150 may fully encapsulate the minor chip 160.

In the present embodiment, the chip package 200 may further comprise a metal cap 270 configured to cover the encapsulant 140. The metal cap 270 may have an opening 271. The opening 271 may be used to expose the external surface 134 of the pick-and-place sheet 131 where a ground circuitry is formed to realize the function of fingerprint recognition. Furthermore, the metal cap 270 may be used to protect the chip package from damages caused by electrostatic discharge (ESD). In addition, the exposed area of the external surface 134 of the pick-and-place sheet 131 through the opening 271 may be used for implementing fingerprint sensing or for receiving external information. The chip package 200 may further comprise a printed circuit board 280. The substrate 110 and the metal cap 270 are individually coupled to the printed circuit board 280. In this way, the jointing stress of the metal cap 270 does not directly impact the encapsulant 140 or the adhesive protective piece 130. Moreover, the external connecting pads 111 of the substrate 110 may be physically and/or electrically connected to a corresponding plurality of connecting pads 281 of the printed circuit board 280 through solder paste or solder balls.

The chip sensing surface 121 includes a fingerprint sensing area 123 where the first die-bonding layer 132 is compliantly attached to the fingerprint sensing area 123. The fingerprint sensing area 123 may be aligned to the opening 271 of the metal cap 270 through the adhesive protective piece 130.

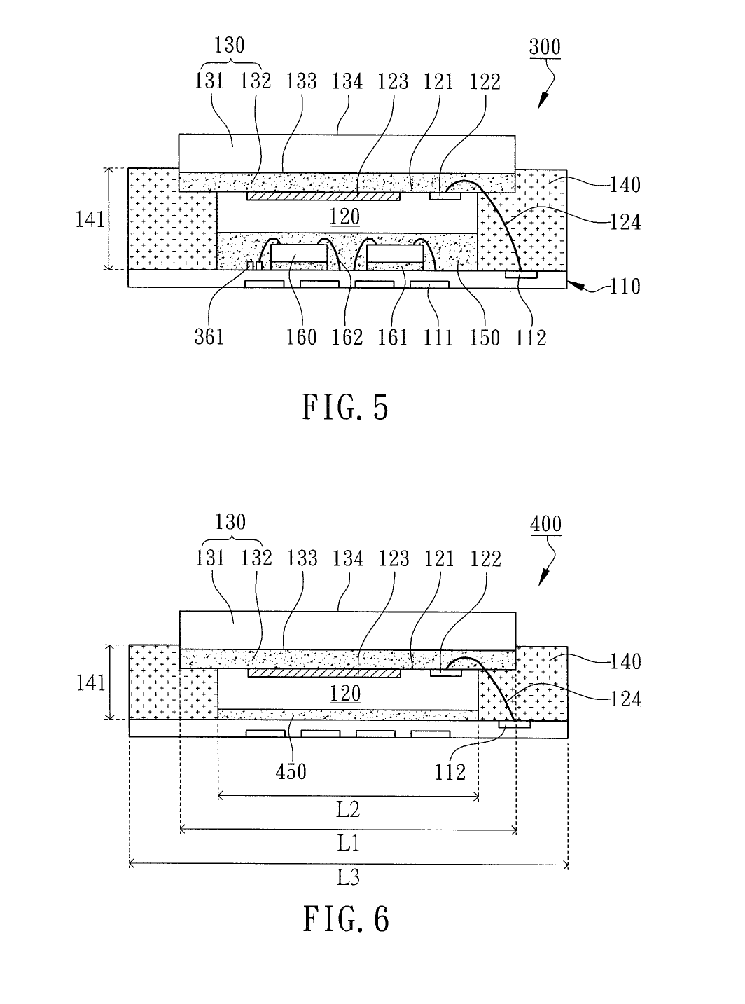

According to the fourth embodiment, a cross-sectional view a chip package 300 having an adhesive protection piece compliantly attached on the chip sensing surface is illustrated in FIG. 5. Except for an additional passive component 361, the chip package 300 is similar the chip package 100 as described in the second embodiment. The corresponding components with the same names and numbers as mentioned in the second embodiment are followed without any further detail description. The chip package 300 comprises a substrate 110, a main chip 120, an adhesive protective piece 130 and an encapsulant 140.

The main chip 120 is disposed on the substrate 110 where the main chip 120 has a chip sensing surface 121 and a connecting terminal 122 on the chip sensing surface 121. The connecting terminal 122 is electrically connected to the internal bonding fingers 112 of the substrate 110 through the bonding wire 124. The adhesive protective piece 130 comprises a pick-and-place sheet 131 and a first die-bonding layer 132 where the adhesive protective piece 130 is compliantly attached on the die sensing surface 121 by a pick-and-place process. In this way, the first die-bonding layer 132 is attached to the chip sensing surface 121 with a constant adhesive gap. The external surface 134 of the pick-and-place sheet 131 is in parallel with the chip sensing surface 121 and may not be affected by the leveling of the substrate 110. The wire loop section of the bonding wire 124 above the main chip 120 is preferably embedded inside the first die-bonding layer 132. Moreover, the encapsulant 140 is formed over the substrate 110. The encapsulant 140 may have an encapsulated height 141 greater than the thickness of the main chip 120 but less than or equal to the external surface 134 of the pick-and-place sheet 131. In this way, the encapsulant 140 may fully encapsulate the main chip 120 and the first die-bonding layer 132 without encapsulating the external surface 134 of the pick-and-place sheet 131. Furthermore, the chip sensing surface 121 further includes a fingerprint sensing area 123 where the first die-bonding layer 132 is also compliantly attached to the fingerprint sensing area 123.

The chip package 300 may further comprise a second die-bonding layer 150 disposed between the main chip 120 and the substrate 110. A covered area of the second die-bonding layer 150 is less than a covered area of the first die-bonding layer 132. At least a minor chip 160 may be attached on the substrate 110 through the third die-bonding layer 161. The least a minor chip 160 is disposed between the main chip 120 and the substrate 110. At least a bonding wire 162 is used to electrically connect the minor chip 160 to the substrate 110. The thickness of the second die-bonding layer 150 is greater than the thickness of the first die-bonding layer 132. In this way, the second die-bonding layer 150 may encapsulate the minor chip 160. The second die-bonding layer 150 may further encapsulate the third die-bonding layer 161 and the bonding wire 162.

In the present embodiment, the chip package 300 may further comprise at least a passive component 361 disposed on the substrate 110 between the main chip 120 and the substrate 110. The second die-bonding layer 150 may further encapsulate the passive component 361. The passive component 361 is implemented to serve as a circuit protector, such as capacitor, inductor or resistor, to protect the minor chip 160 electrically connected to the substrate 110. In addition, components correspondingly smaller than the main chip 120 may be disposed under the main chip 120 to further decrease the footprint of the chip package 300.

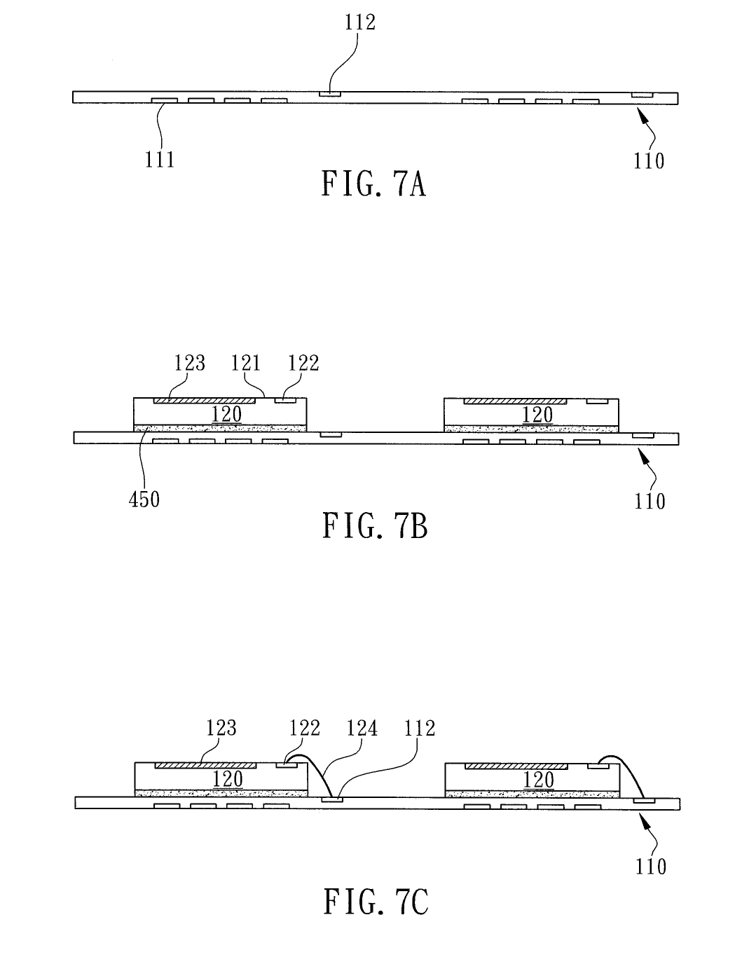

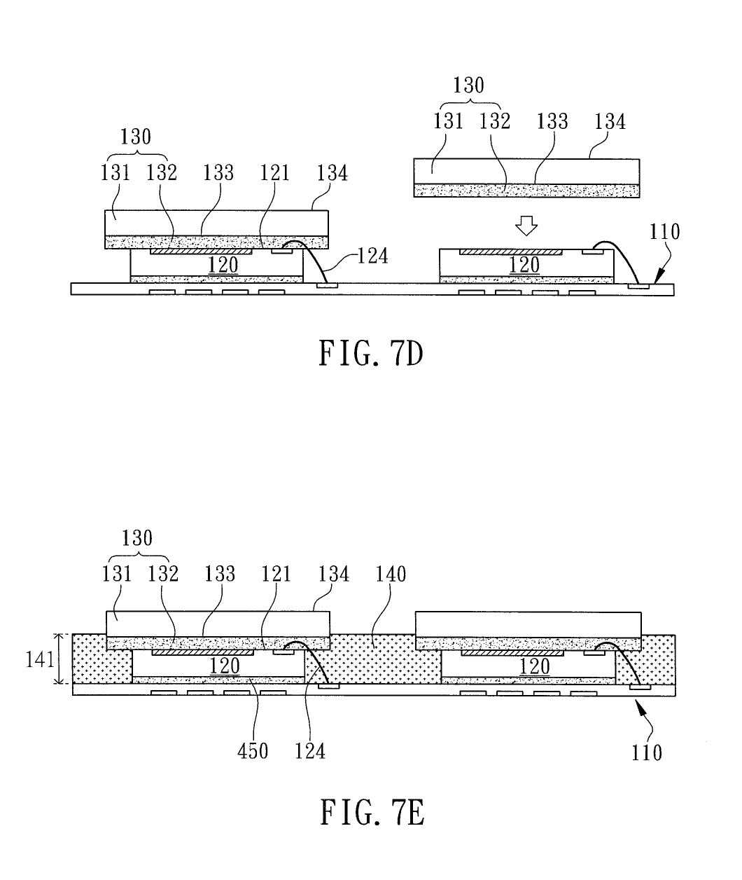

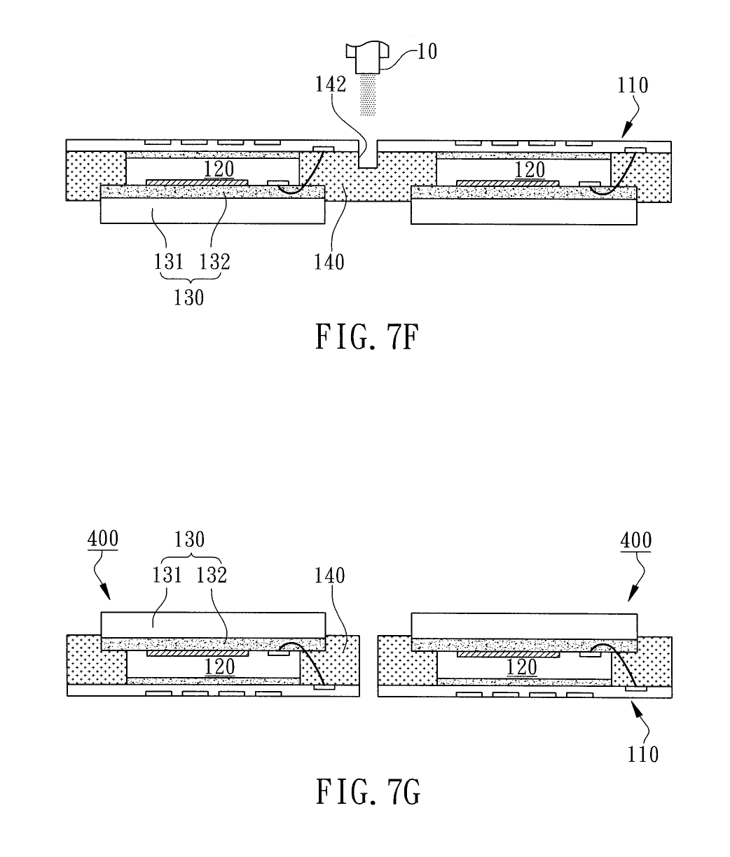

According to the fifth embodiment, a cross-sectional view of a chip package 400 having an adhesive protection piece compliantly attached on the chip sensing surface is illustrated in FIG. 6. FIG. 7A to FIG. 7G illustrate cross-sectional views of the chip package 400, each corresponding to a step of the manufacturing process of the chip package. Except for changing from a multiple-die package to a single-die package, the chip package 400 is almost the same as the chip package 100 as described in the second embodiment. The corresponding components with the same names and numbers as mentioned in the second embodiment are followed without any further detail description. The chip package 400 comprises a substrate 110, a main chip 120 disposed on the substrate 110, an adhesive protective piece 130 compliantly attached on the main chip 120 through pick-and-place process, and an encapsulant 140 disposed on the substrate 110. Furthermore, the chip sensing surface 121 of the main chip 120 includes a fingerprint sensing area 123 where the first die-bonding layer 132 is compliantly attached to the fingerprint sensing area 123.

The chip package 400 further comprises a second die-bonding layer 150 disposed between the main chip 120 and the substrate 110. A covered area of the second die-bonding layer 150 is less than a covered area of the first die-bonding layer 132. Since a second die-bonding layer 450 does not encapsulate any minor chip, the thickness of the chip package 400 may be reduced. The second die-bonding layer 450 may be die-bonding material such as epoxy, Die Attach Film (DAF), or Die Attach Material (DAM).

As shown in FIG. 6, the first die-bonding layer 132 may fully cover the internal surface 133 of the pick-and-place sheet 131. A first dimension L1 of the pick-and-place sheet 131 may be greater than a second dimension L2 of the main chip 120 but less than a third dimension L3 of the substrate 110. In this way, the encapsulant 140 may further encapsulate the peripheries of the pick-and-place sheet 131, thereby, allowing the first die-bonding layer 132 to be completely encapsulated by the encapsulant 140 and avoid the exposure of the die-bonding material.

The steps of the packaging process of the chip package 400 are illustrated through FIG. 7A to FIG. 7G. As shown in FIG. 7A, a substrate 110 is provided. The substrate 110 is fixed on a working station. The substrate 110 has a plurality of external connecting pads 111 and a plurality of internal bonding fingers 112.

Then, as shown in FIG. 7B, the main chip 120 is attached on the substrate 110 through the second die-bonding layer 450. The chip sensing surface 121 of the main chip 120 may comprise the connecting terminal 122 and the fingerprint sensing area 123. The chip sensing surface 121 faces to a direction away from the substrate 110. Then, the second die-bonding layer 450 is cured. Then, as shown in FIG. 7C, the bonding wires 124 are formed to electrically connect the connecting terminals 122 of the main chip 120 to the internal bonding fingers 112 of the substrate 110. Then, as shown in FIG. 7D, a pick-and-place process for attaching the adhesive protective piece 130 is executed, wherein the adhesive protective piece 130 is compliantly attached to the main chip 120. The adhesive protective piece 130 comprises a pick-and-place sheet 131 and a first die-bonding layer 132. The first die-bonding layer 132 is attached to the chip sensing surface 121 with a constant adhesive gap between the internal surface 133 of the pick-and-place sheet 131 and the chip sensing surface 121 of the main chip 120. And, the wire loop sections of the bonding wires 124 above the main chip 120 are preferably embedded inside the first die-bonding layer 132. Then, as shown in FIG. 7E, a molding process is executed to form an encapsulant 140 on the substrate 110 to encapsulate the main chip 120 and the first die-bonding layer 132. The encapsulant 140 has an encapsulated height 141 corresponding to the substrate 110 greater than the thickness of the main chip 120 but less than or equal to the external surface 134 of the pick-and-place sheet 131 to the substrate 110. In this way, the encapsulant 140 fully encapsulates the first die-bonding layer 132 without encapsulating the external surface 134 of the pick-and-place sheet 131. Then, as shown in FIG. 7F and FIG. 7G, a singulation process is executed. Wherein, the laser cutting device 10 may first cut through the substrate 110 then cut through the encapsulant 140 to form a plurality of individual chip packages 400 as shown in FIG. 7G.

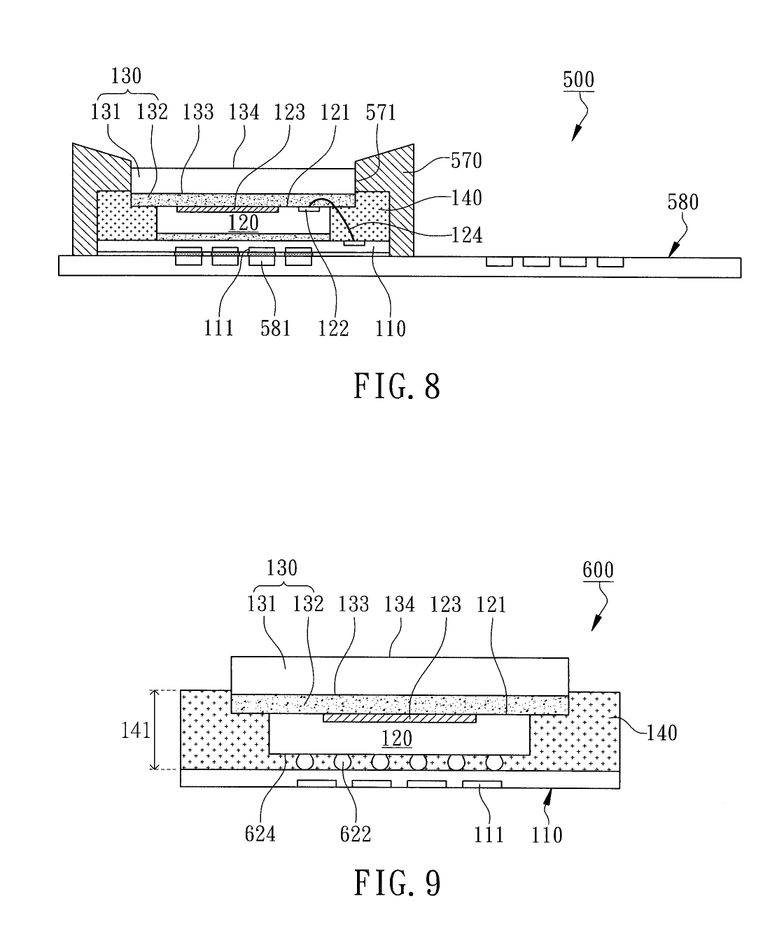

According to the sixth embodiment, a cross-sectional view of a chip package 500 having an adhesive protection piece compliantly attached on the chip sensing surface is illustrated in FIG. 8. Except changing from a multiple-die package to a single-die package and the additional major components such as a metal cap 570 and a printed circuit board 580, the chip package 500 is almost the same as the chip package 100 as described in the second embodiment. The corresponding components with the same names and numbers as mentioned in the second embodiment are followed without any further detail description. The chip package 500 comprises a substrate 110, a main chip 120 disposed on the substrate 110, an adhesive protective piece 130 compliantly attached on the main chip 120 through pick-and-place process, and an encapsulant 140 disposed on the substrate 110. Furthermore, the chip sensing surface 121 of the main chip 120 further includes a fingerprint sensing area 123. The first die-bonding layer 132 is compliantly attached to the fingerprint sensing area 123.

The chip package 500 further comprises a second die-bonding layer 550, such as Die Attach Material (DAM). The second die-bonding layer 550 is disposed between the main chip 120 and the substrate 110. A covered area of the second die-bonding layer 550 may be less than a covered area of the first die-bonding layer 132.

In the present embodiment, the chip package 500 further comprises a metal cap 570 disposed on the encapsulant 140 to cover the encapsulant 140. The metal cap 570 may have an opening 571 to expose the external surface 134 of the pick-and-place sheet 131. The chip package 500 may further comprise a printed circuit board 580. The substrate 110 and the metal cap 570 are individually coupled to the printed circuit board 580. In this way, the jointing stress of the metal cap 570 does not directly impact the encapsulant 140 or the adhesive protective piece 130. Moreover, the external connecting pads 111 of the substrate 110 are physically and electrically connected to a plurality of connecting pads 581 of the printed circuit board 580.

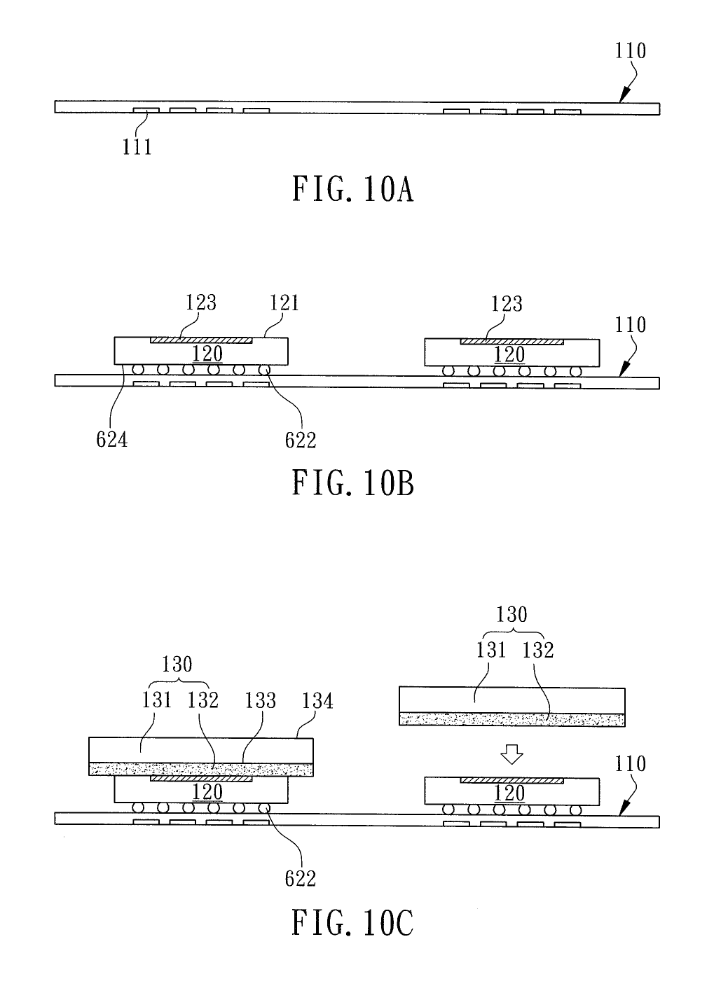

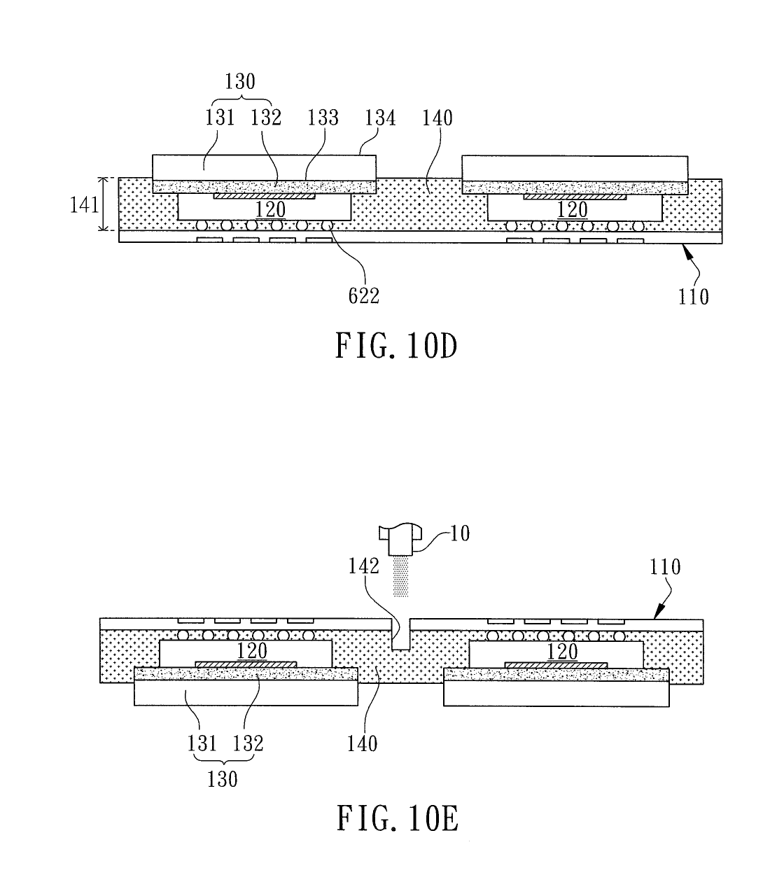

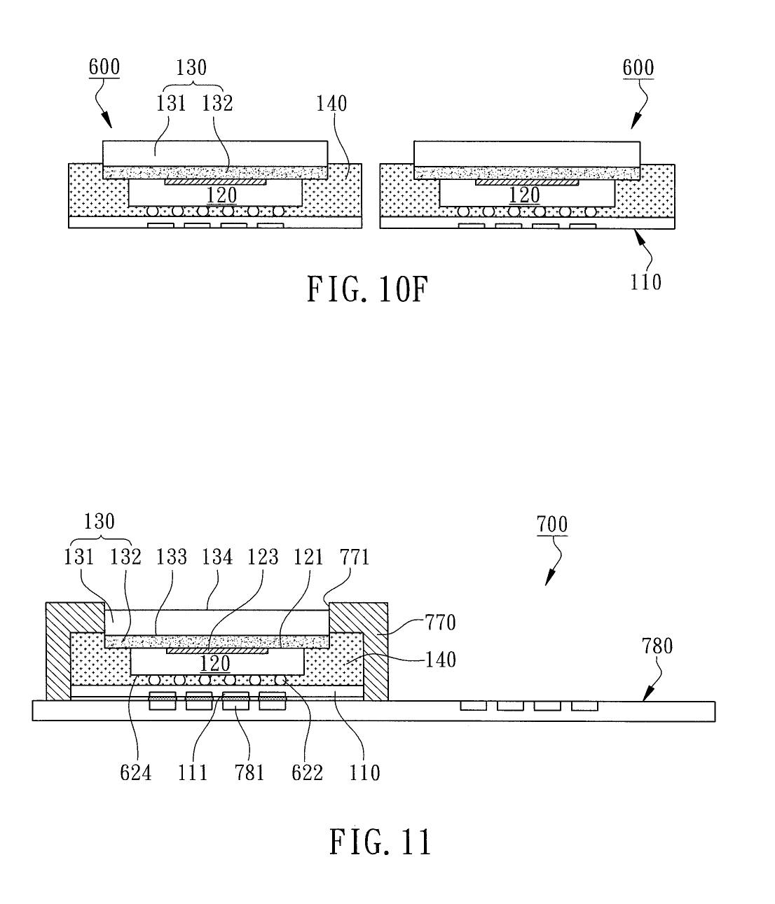

According to the seventh embodiment, a cross-sectional view of a chip package 600 having an adhesive protection piece compliantly attached on the chip sensing surface is illustrated in FIG. 9. FIG. 10A to FIG. 10F illustrate cross-sectional views of the chip package 600, each corresponding to a step of the manufacturing process of the chip package. Except for changing from a multiple-die package to a single-die package and from the wire-bonding interconnection to flip-chip interconnection, the chip package 600 is almost the same as the chip package 100 as described in the second embodiment. The corresponding components with the same names and numbers as mentioned in the second embodiment are followed without any further detail description. The chip package 600 comprises a substrate 110, a main chip 120 disposed on the substrate 110, an adhesive protective piece 130 compliantly attached on the main chip 120 through a pick-and-place process, and an encapsulant 140 disposed on the substrate 110. Furthermore, the chip sensing surface 121 of the main chip 120 further includes a fingerprint sensing area 123. The first die-bonding layer 132 is compliantly attached to the fingerprint sensing area 123.

The main chip 120 has a chip sensing surface 121 and a plurality of connecting terminals 622. The chip sensing surface 121 faces to a direction away from the substrate 110 and the connecting terminals 622 are electrically connected to the substrate 110. The adhesive protective piece 130 comprises a pick-and-place sheet 131 and a first die-bonding layer 132. The pick-and-place sheet 131 has an internal surface 133 and an external surface 134. The first die-bonding layer 132 is disposed on the internal surface 133 of the pick-and-place sheet 131. The first die-bonding layer 132 is attached to the chip sensing surface 121 with a constant adhesive gap between the internal surface 133 of pick-and-place sheet 131 and the chip sensing surface 121 of the main chip 120. The external surface 134 is independent from a leveling of the substrate 110. Moreover, the encapsulant 140 is formed over the substrate 110. The encapsulant 140 has an encapsulated height 141 corresponding to the substrate 110 greater than the thickness of the main chip 120 but less than or equal to the external surface 134 of the pick-and-place sheet 131. In this way, the encapsulant 140 fully encapsulates the first die-bonding layer 132 corresponding to the substrate 110 without encapsulating the external surface 134 of the pick-and-place sheet 131.

In the present embodiment, the connecting terminals 622 are disposed on a bottom surface 624 of the main chip 120, wherein the bottom surface 624 is opposite to the chip sensing surface 121. The connecting terminals 622 include at least a bump to electrically connect the main chip 120 to the substrate 110 through the flip-chip die-bonding process. In this way, the thickness of the first die-bonding layer 132 may be further reduced.

The packaging method of the chip package 600 are further described from FIG. 10A to FIG. 10F. As shown in FIG. 10A, a substrate 110 is provided. The substrate 110 is fixed on a working station. The substrate 110 has a plurality of external connecting pads 111. Then, as shown in FIG. 10B, the main chip 120 is flip-chip bonded on the substrate 110 through the connecting terminals 622 disposed on the bottom surface 624 of the main chip 120. In this way, the main chip 120 is electrically connected to the substrate 110. The chip sensing surface 121 of the main chip 120 includes a fingerprint sensing area 123. The fingerprint sensing area 123 is electrically connected to the connecting terminals 622 through vias formed in through holes on silicon, i.e. through silicon via (TSV), or chip-side circuitry located at opposing surfaces where the chip sensing surface 121 faces to a direction away from the substrate 110. Then, as shown in FIG. 10C, the pick-and-place process of the adhesive protective piece 130 is executed. The adhesive protective piece 130 is compliantly attached to the main chip 120. The adhesive protective piece 130 comprises a pick-and-place sheet 131 and a first die-bonding layer 132. Then, as shown in FIG. 10D, a molding process is executed to form an encapsulant 140 on the substrate 110 to encapsulate the main chip 120 and the first die-bonding layer 132. The encapsulant 140 has an encapsulated height 141 corresponding to the substrate 110 which is greater than the thickness of the main chip 120 but less than or equal to the height of the external surface 134 of the pick-and-place sheet 131 corresponding to the substrate 110. Then, as shown in FIG. 10E, a singulation process is executed. The laser cutting device 10 may firstly cut through the substrate 110 then cut through the encapsulant 140. A plurality of individual chip packages 600 are manufactured after singulation as shown in FIG. 10F.

According to the eighth embodiment, a cross-sectional view of a chip package 700 having an adhesive protection piece compliantly attached on the chip sensing surface is illustrated in FIG. 11. Except the additional major components such as a metal cap 770 and a printed circuit board 780, the chip package 700 is almost the same as the chip package 100 as described in the second embodiment. The corresponding components with the same names and numbers as mentioned in the second embodiment are followed without any further detail description. The chip package 700 comprises a substrate 110, a main chip 120 disposed on the substrate 110, an adhesive protective piece 130 compliantly attached on the main chip 120 by a pick-and-place process, and an encapsulant 140 formed over the substrate 110.

The main chip 120 is disposed on the substrate 110, wherein the main chip 120 has a chip sensing surface 121 and a plurality of connecting terminals 122 at opposing surfaces. The chip sensing surface 121 faces to a direction away from the substrate 110. The connecting terminals 122 are bumps and are electrically connected to the substrate 110 through a flip-chip die-bonding process. The adhesive protective piece 130 may consist essentially of a pick-and-place sheet 131 and a first die-bonding layer 132. The pick-and-place sheet 131 has an internal surface 133 and an external surface 134. The first die-bonding layer 132 is disposed on the internal surface 133 of the pick-and-place sheet 131 before the pick-and-place process. The adhesive protective piece 130 is compliantly attached on the die sensing surface 121 through the pick-and-place process. In this way, the first die-bonding layer 132 is attached to the chip sensing surface 121 with a constant adhesive gap. The external surface 134 of the pick-and-place sheet 131 is parallel to the chip sensing surface 121 and is not affected by the leveling of the substrate 110. The chip sensing surface 121 includes a fingerprint sensing area 123. The first die-bonding layer 132 is compliantly attached to the fingerprint sensing area 123. Moreover, the encapsulant 140 formed on the substrate 110 encapsulates the main chip 120. The encapsulant 140 has an encapsulated height corresponding to the substrate 110 greater than the thickness of the main chip 120 but less than or equal to the height of the external surface 134 of the pick-and-place sheet 131 corresponding to the substrate 110. In this way, the encapsulant 140 fully encapsulates the first die-bonding layer 132 without encapsulating the external surface 134 of the pick-and-place sheet 131.

In the present embodiment, the chip package 700 may further comprise a metal cap 770 disposed on the encapsulant 140. The metal cap 770 is used to cover the encapsulant 140. The metal cap 770 may have an opening 771 to expose the external surface 134 of the pick-and-place sheet 131. The chip package 700 further comprises a printed circuit board 780 where the substrate 110 and the metal cap 770 are individually coupled to the printed circuit board 780. In this way, The jointing stress of the metal cap 770 does not directly impact on the encapsulant 140 or the adhesive protective piece 130. The fingerprint sensing area 123 is aligned within the opening 771 of the metal cap 770 through the adhesive protective piece 130. Moreover, the external connecting pads 111 of the substrate 110 are physically and electrically connected to a plurality of connecting pads 781 of the printed circuit board 780.

According to abovementioned description, the chip package includes an adhesive protection piece compliantly attached on the chip sensing surface. The package structure and manufacturing process for the second embodiment to the eighth embodiment are disclosed. The disclosed processes and structures are used to avoid sensing distortion after an adhesive protective piece is disposed on a sensor chip. Furthermore, the present invention allows the increase in packaging yield and production efficiency. The requirements of Chip Scale Package (CSP) may also be met without having a cavity opening at the bottom or at the sidewall of the sensor chip. By implementing the packaging process, additional package cost may be avoided and structure integrity and strength of the finger-print sensor chip may be maintained. In addition, the chip package further integrates minor chips, passive components, metal caps or a printed circuit board using conventional wire-bonding process or flip-chip die-bonding process to manufacture the mentioned-above multi-chip packages.

The above description of embodiments of this invention is intended to be illustrative but not limited. Other embodiments of this invention are obvious to those skilled in the art in view of the above disclosure which is still covered by and within the scope of the present invention even with any modifications, equivalent variations and adaptations.

What is claimed is:

1. A chip package comprising:
a substrate;
a main chip disposed on the substrate, wherein the main chip has a chip sensing surface and a connecting terminal electrically connected to the substrate;
an adhesive protective piece compliantly attached to the chip sensing surface of the main chip with a constant adhesive gap, the adhesive protective piece having a pick-and-place sheet and a first die-bonding layer, the pick-and-place sheet having an internal surface and an external surface, the first die-bonding layer being disposed between the main chip and the pick-and-place sheet, wherein the external surface of the pick-and-place sheet being parallel to the chip sensing surface is independent from a leveling of the substrate; and
an encapsulant formed on the substrate to encapsulate the main chip, wherein the encapsulant has an encapsulated height corresponding to the substrate greater than the thickness of the main chip but less than a cover height of the external surface of the pick-and-place sheet corresponding to the substrate, wherein the encapsulant encapsulates at least one side of the first die-bonding layer and the external surface of the pick-and-place sheet is exposed from the encapsulant.

2. The chip package as claimed in claim 1, further comprising a second die-bonding layer disposed between the main chip and the substrate, wherein a covered area of the second die-bonding layer is less than a covered area of the first die-bonding layer.

3. The chip package as claimed in claim 2, further comprising at least a minor chip disposed between the main chip and the substrate, wherein the second die-bonding layer encapsulates the minor chip.

4. The chip package as claimed in claim 2, further comprising at least a passive component disposed between the main chip and the substrate, wherein the second die-bonding layer encapsulates the passive component.

5. The chip package as claimed in claim 1, wherein the first die-bonding layer fully covered the internal surface of the pick-and-place sheet with a dimension of the pick-and-place sheet greater than a dimension of the main chip and less than a dimension of the substrate.

6. The chip package as claimed in claim 1, wherein a part of the pick-and-place sheet is encapsulated.

7. The chip package as claimed in claim 1, further comprising a metal cap disposed on the encapsulant and configured to cover the encapsulant, wherein the metal cap has an opening used to expose the external surface of the pick-and-place sheet.

8. The chip package as claimed in claim 7, wherein the substrate and the metal cap are individually coupled to a printed circuit board.

9. The chip package as claimed in claim 1, wherein the connecting terminal is a bonding pad located at a periphery of the chip sensing surface and is electrically connected to the substrate though a bonding wire, wherein a wire loop section of the bonding wire above the main chip is embedded inside the first die-bonding layer.

10. The chip package as claimed in claim 1, wherein the connecting terminal is disposed at a bottom surface of the main chip opposite to the chip sensing surface, wherein the connecting terminal includes at least a bump.

11. The chip package as claimed from claim 1, wherein the chip sensing surface includes a fingerprint sensing area, wherein the first die-bonding layer fully encapsulated the fingerprint sensing area.

12. A chip package comprising:
a substrate;
a main chip disposed on the substrate, the main chip having a chip sensing surface and a connecting terminal electrically connected to the substrate;
an adhesive protective piece disposed on the chip sensing surface of the main chip, the adhesive protective piece having a pick-and-place sheet and a first die-bonding layer disposed between the main chip and the pick-and-place sheet, the pick-and-place sheet having an internal surface and an external surface, wherein the external surface of the pick-and-place sheet being parallel to the chip sensing surface is independent from a leveling of the substrate; and
an encapsulant formed on the substrate configured to encapsulate the main chip and at least one side of the first die-bonding layer, wherein the encapsulant has an encapsulated height corresponding to the substrate greater than a height of the main chip corresponding to the substrate but less than a height of the external surface of the pick-and-place sheet corresponding to the substrate.

13. The chip package as claimed in claim 12, further comprising a second die-bonding layer disposed between the main chip and the substrate, wherein a covered area of the second die-bonding layer is less than a covered area of the first die-bonding layer.

14. The chip package as claimed in claim 13, further comprising at least a minor chip disposed between the main chip and the substrate, wherein the second die-bonding layer encapsulates the minor chip.

15. The chip package as claimed in claim 13, further comprising at least a passive component disposed between the main chip and the substrate, wherein the second die-bonding layer encapsulates the passive component.

16. The chip package as claimed in claim 12, wherein a dimension of the adhesive protective piece is greater than a dimension of the main chip and less than a dimension of the substrate.

17. The chip package as claimed in claim 12, further comprising a metal cap disposed on the encapsulant and configured to cover the encapsulant, the metal cap having a recessed area configured to expose the external surface of the pick-and-place sheet.

18. The chip package as claimed in claim 17, wherein the substrate and the metal cap are individually coupled to a printed circuit board.

19. The chip package as claimed in claim 12, wherein the connecting terminal is a bonding pad disposed on an area around the chip sensing surface and is electrically connected to the substrate though a bonding wire, wherein a part of the bonding wire is embedded inside the first die-bonding layer.

20. The chip package as claimed in claim 12, wherein the connecting terminal is disposed at a bottom surface of the main chip opposite to the chip sensing surface, wherein the connecting terminal includes at least a bump.
